(19) United States
(12) Patent Application Publication
(10) Pub. No.: US 2011/0155227 A1
(43) Pub. Date: Jun. 30, 2011

(54) Electrolyte composition for photoelectric transformation device and photoelectric transformation device manufactured by using the same

(76) Inventors: Tadao Yagi, Yokohama (JP); Yukika Yamada, Yokohama (JP); Yoshitaka Terao, Yokohama (JP)

(21) Appl. No.: 12/929,013

(22) Filed: Dec. 22, 2010

(30) Foreign Application Priority Data
Dec. 25, 2009 (JP) 2009-295942
Nov. 11, 2010 (KR) 10-2010-0112204

(51) Int. Cl. H01L 31/0256; H01G 9/022

(52) U.S. Cl. 136/252; 252/62.2

(57) ABSTRACT

An electrolyte composition for a photoelectric transformation device includes a redox material that is a halide ion, a polyhalide ion, or a combination thereof and a mayenite type compound.

### BACKGROUND

1. Field

This disclosure relates to an electrolyte composition for a photoelectric transformation device and a photoelectric transformation device manufactured by using the same.

2. Description of the Related Art

Studies on a photoelectric transformation device such as solar cell and the like transforming photoenergy into electrical energy have been actively performed to provide clean energy having little environmental impact.

### SUMMARY

According to an embodiment, there is provided an electrolyte composition for a photoelectric transformation device, including a redox material; and a mayenite type compound.

The redox material may be a halide ion, a polyhalide ion, or a combination thereof.

The mayenite type compound may be 12CaO.7Al₂O₃ or 12SrO.7Al₂O₃.

The mayenite type compound may be present in the electrolyte composition in an amount of about 0.1 wt % to 50 wt % based on an entire amount of the electrolyte composition.

The mayenite type compound may include halide ions, polyhalide ions, or a combination thereof inside at least some pores of a crystal lattice of the mayenite type compound such that the halide ions, polyhalide ions, or a combination thereof inside at least some pores of the crystal lattice of the mayenite type compound are unable to combine with a cation.

The electrolyte composition may further include a gel electrolyte, ionic liquid, or a combination thereof.

The ionic liquid may be propyl-2,3-dimethylimidazolium iodide or N-methyl-N′-hexylimidazolium iodide.

The gel electrolyte may be polyacrylonitrile, polyvinylidene fluoride or a polyvinylidene fluoride-hexafluoropropylene copolymer.

According to an embodiment, there is provided a photoelectric transformation device including an electrolyte layer including an electrolyte composition including a redox material and a mayenite type compound.

The redox material may be a halide ion, a polyhalide ion, or a combination thereof.

The mayenite type compound may be present in the electrolyte composition in an amount of about 0.1 wt % to 50 wt % based on an entire amount of the electrolyte composition.

The mayenite type compound may include halide ions, polyhalide ions, or a combination thereof inside at least some pores of a crystal lattice of the mayenite type compound such that the halide ions, polyhalide ions, or a combination thereof inside at least some pores of the crystal lattice of the mayenite type compound are unable to combine with a cation.

The electrolyte composition may further include a gel electrolyte, ionic liquid, or a combination thereof

The photoelectric transformation device may be a dye sensitized solar cell.

According to an embodiment, there is provided a solar cell including an electrolyte layer between a photoelectrode and a counter electrode, the electrolyte including an electrolyte composition that includes a mayenite type compound.

The electrolyte may further include a redox material that is a halide ion, a polyhalide ion, or a combination thereof.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of a photoelectric transformation device according to one embodiment.

FIG. 2 illustrates a schematic view showing a working mechanism of a photoelectric transformation device shown in FIG. 1.

FIG. 3 illustrates crystal structure of the mayenite type compound included in an electrolyte composition according to one embodiment.

FIG. 4 illustrates ion conduction in the electrolyte solution according to one embodiment.

### DETAILED DESCRIPTION

Japanese Patent Application No. 2009-295942 filed on Dec. 25, 2009, and Korean Patent Application No. 10-2010-0112204, filed on Nov. 11, 2010, in the Korean Intellectual Property Office, and entitled: “Electrolyte Composition for Photoelectric Transformation Device and Photoelectric Transformation Device Manufactured by Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will also be understood that when a layer is referred to as being “between” two layers, it can be the only layer between the two layers, or one or more intervening layers may also be present. Like reference numerals refer to like elements throughout.

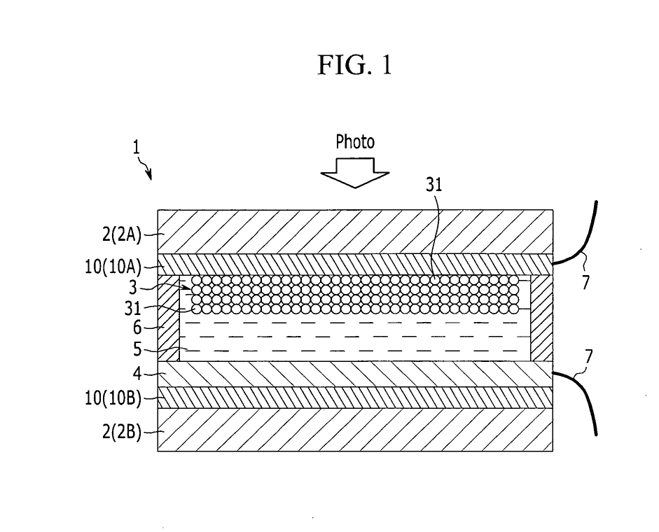

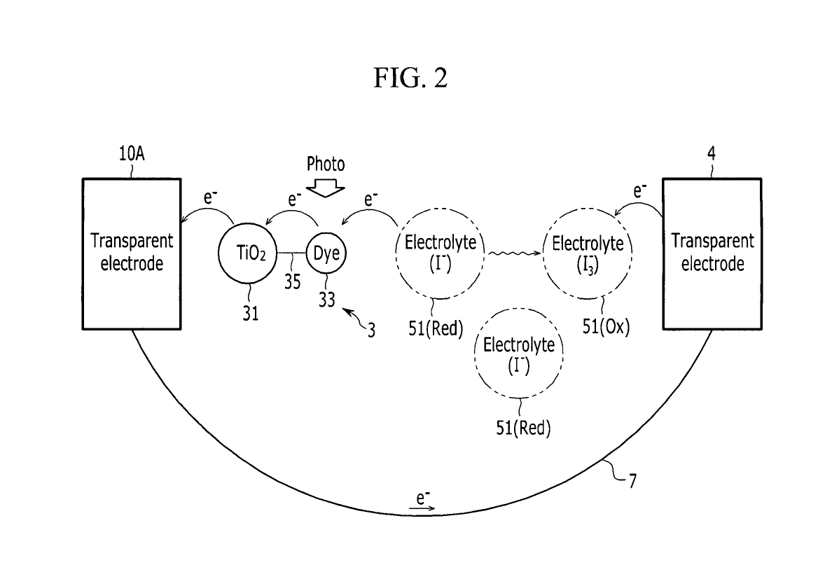

Referring to FIGS. 1 and 2, illustrated is a photoelectric transformation device according to one embodiment. FIG. 1 illustrates a cross-sectional view of a photoelectric transformation device according to one embodiment, and FIG. 2 illustrates a schematic view showing mechanism of the photoelectric transformation device shown in FIG. 1. FIG. 1 shows a dye sensitized solar cell 1 including a Gratzel cell as an example of the photoelectric transformation device.

Referring to FIG. 1, the photoelectric transformation device 1 according to one embodiment includes two substrates 2 (2A and 2B) facing each other, two transparent electrode 10 (10A and 10B), a photoelectrode 3, a counter electrode 4, an electrolyte solution 5, a spacer 6, and a lead wire 7.

Substrate

Two substrates 2 (2A and 2B) are disposed to face each other with a predetermined gap therebetween. The material for each substrate 2 is not specifically limited as long as it is a transparent material having minimal light adsorption of extraneous light (solar light etc.) from the visible ray region to the near infrared ray region. The substrate 2 may be, for example, a glass substrate such as quartz, common glass, BK7, lead glass, or the like; a resin substrate such as polyethylene terephthalate, polyethylene naphthalate, polyimide, polyester, polyethylene, polycarbonate, polyvinylbutyrate, polypropylene, tetraacetyl cellulose, syndiotactic polystyrene, polyphenylene sulfide, polyarylate, polysulfone, polyester sulfone, polyetherimide, cyclic polyolefin, phenoxy bromide, vinyl chloride, and the like.

Transparent Electrode

The transparent electrodes 10 (10A and 10B) may be a transparent conductive substrates. One of the transparent electrodes 10A and 10B may be formed on a surface at least one of a light incident side of the two substrates 2A and 2B. In order to improve photoelectric transformation efficiency, the sheet resistance (surface resistance) of the electrode substrates 10 may be decreased by as much as possible, for example, down to 20 Ω/cm² (Ω/sq) or less. The transparent electrode 10 generally has high sheet resistance (about 10 Ω/sq or more) of electrode substrate 10, and may be provided to prevent a generated current from being converted into Joule heat in a substrate having relatively low conductivity such as TCO to deteriorate the photoelectric transformation efficiency. When a photoelectric transformation device 1 such as a dye sensitized solar cell made larger, photoelectric transformation efficiency may be reduced. A metal line (current-collecting electrode) for transferring excited electrons that arrive at the transparent electrode 10A from the photoelectrode 3, into a wire 7, may be provided on the surface of the transparent electrode 10,

However, it is not necessary to provide the transparent electrode 10B on the surface of the substrate 2B facing the substrate 2A, and it is not necessary for such an electrode 10B to be transparent (i.e., less light adsorption in the region from the visible ray region to the near infrared ray region of extraneous light of the photoelectric transformation device 1) even if the electrode 10B is provided. The electrode 10B may be a conductive substrate.

Transparent electrodes 10A and 10B are stacked on one side of respective substrates 2A and 2B while facing each other and formed of, for example, a transparent conductive oxide (TCO) in a form of a film. The transparent conductive oxide (TCO) is not specifically limited and may be a conductive material that has a low absorption in the region from the visible ray to the infrared ray of the extraneous light of the photoelectric transformation device 1. The transparent conductive oxide may include a metal oxide having good conductivity such as indium tin oxide (ITO), tin oxide (SnO₂), fluorine-doped tin oxide (FTO), antimony-included tin oxide (ITO/ATO), zinc oxide (ZnO₂), and the like.

Photoelectrode

In the photoelectric transformation device 1, the photoelectrode 3 may be an inorganic metal oxide semiconductor layer having a phototransformation function and may be formed with a porous layer

For example, as shown in FIG. 1, the photoelectrode 3 may be formed by laminating a particulate 31 of an inorganic metal oxide semiconductor (hereinafter referred to a “metal oxide particulate 31”) such as TiO₂ or the like on the surface of the transparent electrode 10. is the photoelectrode 3 may be a porous body (nanoporous layer) including nanometer-sized pores in the laminated metal oxide particulate 31. The photoelectrode 3 may be formed as a porous body including a plurality of small pores, so that the surface area of the photoelectrode 3 may be increased and so that a large amount of sensitizing dye units 33 may be connected to the surface of the metal oxide particulate 31. Thereby, the dye sensitized solar cell 1 may have high photoelectric transformation efficiency.

As shown in FIG. 2, sensitizing dye units 33 may be connected to the surface of the metal oxide particulate 31 through a connecting group 35 to provide a photoelectrode 3 in which the inorganic metal oxide semiconductor is sensitized. The term “connection” indicates that the inorganic metal oxide semiconductor may be chemically and/or physically bound with the sensitizing dye (for example, binding by adsorption or the like). Accordingly, the term “connecting group” may refer to the inclusion of an anchor group or an adsorbing group as well as a chemical functional group.

FIG. 2 schematically shows only one sensitizing dye unit 33 connected to the surface of the metal oxide particulate 31; however, it is to be understood that a plurality of sensitizing dye units 33 may be connected to the surface of the metal oxide particulate 31. In order to improve the electrical output of the photoelectric transformation device 1, it is desirable to increase the number of sensitizing dye units 33 connected to the surface of metal oxide particulate 31 as much as possible and to coat a plurality of sensitizing dye units 33 on the surface of metal oxide particulate 31 as widely as possible. However, when the number of the coated sensitizing dye units 33 is excessively increased, an excited electron may be lost due to interaction among adjacent sensitizing dye units 33, losing electrical energy. Thus, a co-adsorption material such as deoxycholic acid and the like may be used to coat the sensitizing dye units 33 to an appropriate separation distance of the sensitizing dye units 33 from each other.

The photoelectrode 3 may be formed by laminating the metal oxide particulate 31 having a primary particle that has a number average particle diameter ranging from about 20 nm to about 100 nm in more than one layer. The photoelectrode 3 may have a layer thickness of several μm (e.g, 10 μm or less). When the photoelectrode 3 has a layer thickness of less than several μm, the light transmitted through the photoelectrode 3 may be increased and thus, the sensitizing dye units 33 may be insufficiently excited, failing in securing efficient photoelectric transformation efficiency. On the other hand, when the photoelectrode 3 has a layer thickness of more than several micrometers, the distance between the surface of the photoelectrode 3 (a surface contacting the electrolyte solution 5) and the surface of an electrode (an interface between the photoelectrode 3 and the transparent electrode 10) is increased, so that it may be difficult to effectively transmit generated excited electrons to the electric conductive surface. Therefore, an excessively thick photoelectrode 3 may not provide good transformation efficiency.

Hereinafter, a metal oxide particulate 31 and sensitizing dye units 33 for a photoelectrode 3 according to one embodiment will now be described.

Metal Oxide Particulate

In general, the inorganic metal oxide semiconductor photoelectrically transforms a light in a predetermined wavelength region, such as, for example, a light in the region from visible to near infrared, by providing the sensitizing dye units 33 connected to the surface of the metal oxide particulate 31. The compound for the metal oxide particulate 31 is not specifically limited and may enhance the photoelectric transformation function by being connected with the sensitizing dye unit 33. Compounds for the metal oxide particular 31 may include, for example, titanium oxide, tin oxide, tungsten oxide, zinc oxide, indium oxide, niobium oxide, iron oxide, nickel oxide, cobalt oxide, strontium oxide, tantalum oxide, antimony oxide, oxides of lanthanide elements, yttrium oxide, vanadium oxide, and the like. As the surface of the metal oxide particulate 31 is sensitized by the sensitizing dye unit 33, the conduction band of the inorganic metal oxide may be disposed where it may easily receive electrons from the photoexcitation trap of the sensitizing dye unit 33. The compound for a metal oxide particulate 31 may include, as more specific examples, titanium oxide, tin oxide, zinc oxide, niobium oxide, and the like. As a more specific example, titanium oxide may be desirable in the view of cost and environmental sanitation. The metal oxide particulate 31 may be a single kind of inorganic metal oxide or a combination of multiple kinds thereof.

Sensitizing Dye

The sensitizing dye unit 33 is not specifically limited. The sensitizing dye 33 photoelectrically may transform a light in the region having no photoelectric transformation function (for example, in the region from visible ray to near infrared ray)

The sensitizing dye unit 33 may include, for example, an azo-based dye, a quinacridone-based dye, a diketopyrrolopyrrole-based dye, a squarylium-based dye, a cyanine-based dye, a merocyanine-based dye, a triphenylmethane-based dye, a xanthene-based dye, a porphyrin-based dye, a chlorophyll-based dye, a ruthenium complex-based dye, an indigo-based dye, a perylene-based dye, a dioxadine-based dye, an anthraquinone-based dye, a phthalocyanine-based dye, a naphthalocyanine-based dye, and derivatives thereof or the like.

The sensitizing dye unit 33 may include a functional group of a connecting group 35 that is capable of connecting to the surface of the metal oxide particulate 31 in order to promptly transmit the excited electrons of the photo-excited dye into the conductive band of the inorganic metal oxide. The functional group is not specifically limited and may include, for example, a carboxyl group, a hydroxyl group, a hydroxamic acid group, a sulfonic acid group, a phosphonic acid group, a phosphinic acid group or the like.

Counter Electrode

The counter electrode 4 may be a positive electrode in a photoelectric transformation device 1 and may be a film disposed facing the photoelectrode 3, on the surface of the transparent electrode 10B facing the transparent electrode 10A that includes the photoelectrode 3 thereon. The counter electrode 4 is disposed to face the photoelectrode 3 on the surface of the transparent electrode 10B in the region surrounded by two transparent electrodes 10 and the spacer 6. A metal catalyst layer having conductivity may be disposed on the surface of the counter electrode 4 facing the photoelectrode 3. The conductive material for a metal catalyst layer of the counter electrode 4 may include, for example, a metal such as, for example, platinum, gold, silver, copper, aluminum, rhodium, indium, and the like; a metal oxide such as, for example, indium tin oxide (ITO), tin oxide, fluorine doped tin oxide, zinc oxide, and the like; a conductive carbon material; a conductive organic material, or a combination thereof. The layer thickness of the counter electrode 4 is not specifically limited, The layer thickness may range, for example, from about 5 nm to about 10 μm.

Lead wires 7 may be respectively connected to the transparent electrode 10A that is formed with the photoelectrode 3, and the counter electrode 4. The lead wire 7 from the transparent electrode 10A and the lead wire 7 from the counter electrode 4 may be connected outside of the dye sensitized solar cell 1 to provide a current circuit.

In addition, the transparent electrode 10A and the counter electrode 4 may be partitioned by a spacer 6 leaving a predetermined gap therebetween. The spacer 6 may be formed along the circumference of the transparent electrode 10A and the counter electrode 4. The spacer may seal the space between the transparent electrode 10A and the counter electrode 4. The spacer 6 may be a resin having a high sealing property and high corrosion resistance. For example, the spacer 6 may include a film thermoplastic resin, a photo-curable resin, an ionomer resin, a glass frit, and the like. The ionomer resin may include, for example, Himilan (trade name) manufactured by DuPont-Mitsui Polychemicals Co., Ltd., or the like.

Electrolyte Solution

An electrolyte solution 5 may be injected into the space between the transparent electrode 10A and the counter electrode 4 and sealed therein by the spacer 6. The electrolyte solution 5 that is an electrolyte composition according to one embodiment may include, for example, an electrolyte, a solvent, and various additives. Specifically, the electrolyte solution 5 includes a mayenite type compound, which will be described.

The electrolyte may include a redox material such as an I₃⁻/I⁻-based or Br₃⁻/Br⁻-based electrolyte. The electrolyte may include, for example, a mixture of I₂ and iodide (LiI, NaI, KI, CsI, MgI₂, CaI₂, CuI, tetraalkyl ammonium iodide, pyridinium iodide, imidazolium iodide, and the like), a mixture of Br₂ and bromide (LiBr etc.), an organic molten salt compound, and the like, which are dissolved in a solvent that will be described, but the electrolyte is not limited thereto. The term “organic molten salt compound” may refer to a compound consisting of an organic cation and an inorganic or organic anion, and has a melting point of room temperature or less.

The organic cation of the organic molten salt compound may include an aromatic cation and/or an aliphatic cation. The aromatic cations may include, for example N-alkyl-N′-alkylimidazolium cations such as N-methyl-N′-ethylimidazolium cations, N-methyl-N′-n-propylimidazolium cations, N-methyl-N′-n-hexylimidazolium cations, and the like, or N-alkylpyridinium cations such as N-hexylpyridinium cation, N-butylpyridinium cation, and the like. The aliphatic cations include, for example aliphatic cations such as N,N,N-trimethyl-N-propylammonium cations, alicyclic cations such as N,N-methyl pyrrolidinium cations, and the like.

The inorganic or organic anions of the organic molten salt compound may include, for example halide ions such as chloride ions, bromide ions, iodide ions, or the like, inorganic anions such as phosphorus hexafluoride ions, boron tetrafluoride ions, methane sulphonic trifluoride ions, perchloric acid ions, hypochloric acid ions, chloric acid ions, sulfonic acid ions, phosphoric acid ions, or the like, or amide anions or imide anions such as bis(trifluoromethylsulfonyl)imide ions or the like.

Examples of an organic molten salt compound are disclosed in Inorganic Chemistry, vol. 35 (1996); p. 1168 to p. 1178, incorporated herein by reference.

The mentioned iodide, bromide, or the like may be used singularly or as a mixture thereof. For example, the electrolyte may be a mixture of I₂ and iodide (for example, I₂ and LiI), pyridinium iodide, or imidazolium iodide or the like, but is not limited thereto.

The electrolyte solution 5 may have a concentration of I₂ of about 0.01 M to about 0.5 M. Either or both of iodide and bromide (a mixture thereof in the case of multiple kinds thereof) may have a concentration of about 0.1 M to about 15 M.

The solvent for the electrolyte solution 5 may be a compound providing excellent ion conductivity. Such a solvent may include a liquid solvent, for example: ether compounds such as dioxane, diethylether, or the like; linear ethers such as ethylene glycol dialkylether, propylene glycol dialkylether, polyethylene glycol dialkylether, polypropylene glycol dialkylether, or the like; alcohols such as methanol, ethanol, ethylene glycol monoalkylether, propylene glycol monoalkylether, polyethylene glycol monoalkylether, polypropylene glycol monoalkylether, or the like; polyhydric alcohols such as ethylene glycol, propylene glycol, polyethylene glycol, polypropylene glycol, glycerine, or the like; nitrile compounds such as acetonitrile, glutarodinitrile, methoxy acetonitrile, propionitrile, benzonitrile, or the like; carbonate compounds such as ethylene carbonate, propylene carbonate, or the like; heterocyclic ring compounds such as 3-methyl-2-oxazolidinone or the like; aprotic polar materials such as dimethyl sulfoxide, sulfolane, or the like; or water and the like. The solvents may be used singularly or as a mixture thereof. To provide a solid (including a gel) solvent, a polymer may be added to a liquid solvent. In this case, a polymer such as polyacrylonitrile, polyvinylidene fluoride, or the like may be added to the liquid solvent, or a multi-functional monomer including an ethylenic unsaturated group may be polymerized in the liquid solvent to provide a solid solvent. For the solvent for the electrolyte solution 5, an ionic liquid that exists as a liquid at a room temperature may be used. The ionic liquid may suppress evaporation of the electrolyte solution 5 resulting in an improvement of durability of a photoelectric transformation device 1.

The electrolyte solution 5 may also include a hole transport material such as CuI, CuSCN (these compounds are p-type semiconductors not requiring a liquid solvent and act as an electrolyte), or

2,2′,7,7′-tetrakis(N,N-di-p-methoxyphenylamine)-9,9′-spirobifluorene disclosed in Nature, vol. 395 (Oct. 8, 1998), p 583 to p 585, incorporated herein by reference, or the like.

Other additives may be further added to the electrolyte solution 5 in order to improve the durability or the electrical output of the photoelectric transformation device 1. For example, inorganic salts such as magnesium iodide or the like may be added in order to improve the durability. Amines such as t-butyl pyridine, 2-picoline, 2,6-lutidine, or the like; steroids such as deoxy cholic acid or the like; monosaccharides or sugar alcohols such as glucose, glucosamine, glucuronic acid, or the like; disaccharides such as maltose or the like; linear oligosaccharides such as raffinose or the like; cyclic oligosaccharides such as cyclodextrin or the like; or hydrolysis oligosaccharides such as lacto oligosaccharide or the like may be added in order to improve the electrical output.

In addition, the thickness of the layer injected with the electrolyte solution 5 and sealed is not specifically limited, but the thickness may be determined to prevent direct contact between the counter electrode 4 and the photoelectrode 3 adsorbed with the dye. For example, the thickness of the electrolyte solution 5 layer may range from about 0.1 μm to about 100 μm.

The mayenite type compound included in an electrolyte solution 5 according to one embodiment will be described below.

Working Mechanism of Photoelectric Transformation Device

Hereinafter, referring to FIGS. 1 and 2, the working mechanism of an example of a photoelectric transformation device is described.

In a photoelectrode 3 including the metal oxide particulate 31 and a sensitizing dye units 33 connected thereto on the surface through a connecting group 35, a light (a solar light) transmitting a substrate 2A and entering a cell is absorbed in a sensitizing dye unit 33 connected to the surface of the metal oxide particulate 31 as shown in FIGS. 1 and 2. The sensitizing dye unit 33 absorbing the light is excited from the electronic ground state by MLCT (metal to ligand charge transfer) and emits excited electrons. The excited electrons are injected into the conduction band of a metal oxide (e.g., TiO₂) of the metal oxide particulate 31 through a connecting group 35. As a result, the sensitizing dye unit 33 is oxidized. The sensitizing dye unit 33 may have a lower energy level than the conduction band of the metal oxide (semiconductor) to efficiently inject excited electrons into the metal oxide.

The excited electrons injected into the conduction band of the metal oxide may reach a transparent electrode 10A through the layer of the metal oxide particulate 31 and travel to the counter electrode 4 through the lead wire 7. The sensitizing dye unit 33 lacking electrons (oxidation state) due to the emission of excited electrons receives electrons from a reduced body (such as, for example, I⁻) of an electrolyte (Red) 51 and returns to a a ground state. An electrolyte (Ox) 51 that becomes an oxidizing body (for example, I₃⁻) after supplying the sensitizing dye unit 33 with electrons may diffuse to a counter electrode 4 and receive electrons therefrom and return to a reduced state as the electrolyte (Red) 51. An electrolyte 51 (Ox) may also receive electrons from other electrolytes 51 (Red), for example, due to hopping conduction and the like as well as receiving electrons when the electrolyte 51 (Ox) diffuses into a counter electrode 4.

Characteristic of Electrolyte Layer According to One Embodiment

Hereinafter, illustrated is an electrolyte layer in which an electrolyte solution 5 according to one embodiment is included and sealed in detail. The electrolyte layer may include a redox material (for example, I⁻/I₃⁻-based, Br⁻/Br₃⁻ based, and the like) and a mayenite type compound as an electrolyte composition.

Mayenite Type Compound

The term “mayenite type compound” may refer to mayenite, which is a cement mineral with a cubic crystal structure. The term may also refer to a compound with a similar crystal structure to mayenite. For example, the mayenite-type compound may have a composition such as 12CaO.7Al₂O₃ (hereinafter, referred to be as ‘C12A7’), 12SrO.7Al₂O₃, or the like and a cage-type crystal structure due to a bonding of Ca²⁺, Al³⁺, and O²⁻. The mayenite type compound crystal may be in the form of a crystal lattice having twelve fine pores with a diameter of about 0.4 nm to about 0.6 nm per unit lattice in the crystal lattice. For example, C12A7 crystal may include two O²⁻ per unit lattice in the pore. C12A7 crystal may have a structure represented by [Ca₂₄Al₂₈O₆₄]⁴⁺.2O²⁻. The O²⁻ in the C12A7 crystal may be bound inside a pore at a state in which it is unable to bind with a cation. The O²⁻ in such a state may be referred to as the free oxygen, to distinguish from oxygen that is part of the structure of the crystal lattice (for example, refer to H. B. Bartl and T. Scheller, Neuses Jarhrb. Minerai, Monatsh, 1970, p. 547) incorporated herein by reference.

A crystal substantially represented by [Ca₂₄Al₂₈O₆₄]⁴⁺.4F⁻ or [Ca₂₄Al₂₈O₆₄]⁴⁺.4Cl⁻ may be obtained by substituting the free oxygen with fluorine or chlorine in the structure (for example, refer to P. P. Williams, Acta Crystallogr., Sec. B, 29, 1550 (1973), H. Pollmann, F. Kammerer, J. Goske, J. Neubauer, Friedrich-Alexander-Univ. Erlangen-Nurnberg, Germany, ICDD Grant-in-Aid, 1994, both of which are incorporated herein by reference).

According to a present embodiment, unexpected beneficial effects may be provided to a photoelectric transformation device by adding a mayenite type compound to an electrolyte composition including a redox material that is a halide ion (I⁻, Br⁻, or the like), a polyhalide ion (I₃⁻, Br₃⁻, or the like), or a combination thereof.

Effects of Adding Mayenite-Type Compound to Electrolyte Composition

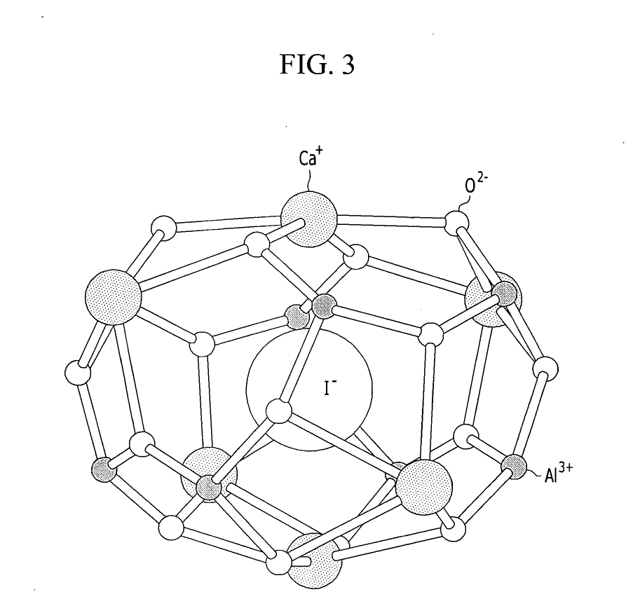

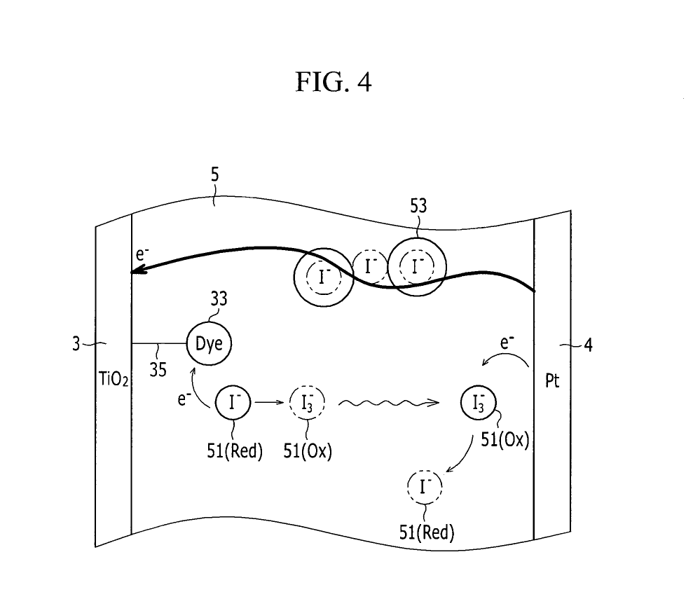

Hereinafter, FIGS. 3 and 4 illustrate effects of adding a mayenite-type compound to an electrolyte composition for a photoelectric transformation device. FIG. 3 illustrates one example of the crystal structure of a mayenite type compound included in an electrolyte composition according to one embodiment. FIG. 4 illustrates one example of ion conduction in an electrolyte solution according to one embodiment.

An electrolyte for a photoelectric transformation device such as a dye sensitized solar cell and the like may include a volatile organic solvent. However, a volatile organic solvent may have a problem of volatilizing an electrolyte solution or leaking it out of the device. When a gel electrolyte solution, an ionic liquid, or a combination thereof is used as a solvent, may be volatilization or leaking of the electrolyte solution may be suppressed. However, a gel electrolyte solution, an ionic liquid, or a combination thereof may have an increased viscosity and thus, deteriorated ion conductivity, degrading performance of a photoelectric transformation device such as photoelectric transformation efficiency, life-span, or the like. Accordingly, there may be trade-off problems of an electrolyte solution between volatilization or leakage out of a device and ion conductivity deterioration.

According to one embodiment, trade-off problems between volatilization or leakage of an electrolyte solution and ion conductivity deterioration may be solved by adding a mayenite-type compound to an electrolyte composition for a photoelectric transformation device.

Structure of Mayenite-Type Compound According to One Embodiment

According to one embodiment, a mayenite-type compound included in an electrolyte composition for a photoelectric transformation device may be a crystal type such as C12A7 and the like including O²⁻ in a crystal lattice, a C12A7 electride-type and the like including an electron substituted for O²⁻, a type including a halide ion, a polyhalide ion, or a combination thereof substituted for O²⁻ but is not limited thereto.

When a mayenite-type compound is added to an electrolyte composition a redox material selected from group consisting of a halide ion, a polyhalide ion, and a combination thereof and surrounded with the halide ion, the polyhalide ion, or a combination thereof, these ions may be accepted into a pore in the crystal lattice of the mayenite type compound as schematically illustrated in FIG. 3. The halide ion, the polyhalide ion, or a combination thereof accepted into a pore in the crystal lattice of the mayenite type compound is unable to combine with a cation.

When the mayenite type compound includes a halide ion, a polyhalide ion, or a combination thereof in pores of the crystal lattice, ion conductivity may be improved. If ions included in the pore of the mayenite type compound are bound therein and unable to combine with a cation, electrons therein may be easily detached. A mayenite type compound including a halide ion, a polyhalide ion, or a combination thereof in which electrons may be easily detached may be dispersed in an electrolyte solution. Accordingly, although an electrolyte solution may have a high viscosity and may not easily disperse a halide ion or a polyhalide ion, charges may be easily transferred through an ion exchange reaction in which electrons are exchanged with a halide ion or a polyhalide ion included in a mayenite-type compound widely dispersed therein.

Improvement Effect of Ion Conductivity

As shown in FIG. 4, an electrolyte solution 5 for a photoelectric transformation device such as a dye sensitized solar cell may include a redox material including an iodide ion (I⁻) as an electrolyte 51 (Red) in a reduced form and triiodide ions (I₃⁻) as an electrolyte 51 (Ox) in an oxidized form. A sensitizing dye unit 33 may absorb light energy (hv) and emit electrons. A titanium oxide TiO₂, a semiconductor, (or any of the materials described above as a metal oxide particulate 31) may receive the emitted electrons and transfer the emitted electrons to a photoelectrode 3. A hole (h+) remaining in the sensitizing dye unit 33 may be reduced by I⁻, an electrolyte 51 (Red) in a reduced form. The I⁻ may be oxidized into I₃⁻. The oxidized I₃⁻ may diffuse into an electrolyte solution 5 until the oxidized I₃⁻ approaches a counter electrode 4 and receives electrons from the counter electrode 4 and thus, is reduced back into I⁻.

The diffusion speed of the iodide ion (I⁻) may play an important role in improving ion conductivity and thus, improving photoelectric transformation efficiency. As discussed herein, if the electrolyte I⁻ is mainly diffused through physical diffusion, when a gel electrolyte, a ionic liquid, or a combination thereof are used as a solvent with higher boiling point or vapor pressure to suppress volatilization of a solvent and the like, the electrolyte solution 5 may have increased viscosity and thus, decreased diffusion speed and deteriorated ion conductivity. As a result, a photoelectric transformation device may have deteriorated performances such as transformation efficiency, life-span, or the like.

On the other hand, when an electrolyte solution 5 has high concentration of iodide ions, charges may be transferred through ion exchange reaction requiring no direct ion transfer. According to one embodiment and without being limited to any particular theory, when a mayenite-type compound 53 is added to an electrolyte solution 5, interactions such as complex, absorption, or the like may occur between iodide ions and the mayenite-type compound. Accordingly, an electrolyte solution 5 may have a locally increased concentration of iodide ions, and charges may be increasingly transferred (so-called hopping conduction) through ion exchange reaction as shown by a long arrow in FIG. 4. As a result, the electrolyte solution may have improved ion conductivity, improving performance of a photoelectric transformation device such as transformation efficiency, life-span, or the like.

Therefore, the electrolyte composition may have suppressed volatilization and the like of an electrolyte solution and simultaneously, avoid degradation of performance, such as transformation efficiency and the like, due to deterioration of ion conductivity.

Amount of Mayenite-Type Compound

As described above, charges may be transferred through an ion exchange reaction by locally increasing the concentration of iodide ions in the electrolyte composition (an electrolyte solution). A mayenite-type compound may be included in an amount ranging from about 0.1 wt % to about 50 wt % based on the entire amount of the electrolyte composition. When the mayenite type compound is included in an amount of about 0.1 wt % or more, the mayenite type compound may effectively promote charge transfer through ion exchange reaction and improve ion conductivity. However, when the mayenite type compound is included in an amount greater than 50%, halide ions bound in the mayenite type compound may be set free (thus, supplying electrons and combining with cations). Since the halide ions lose a balance, a photoelectric transformation device may have deteriorated characteristics. In addition, the mayenite type compound may occupy most of the electrolyte composition components, sharply deteriorating the fluidity of an electrolyte composition. Thus, it may be difficult to inject the electrolyte composition into or coat the electrolyte composition onto a photoelectric transformation device. Accordingly, the mayenite type compound may be included in an amount of about 50 wt % or less.

Method of Manufacturing Photoelectric Transformation Device

Hereinbefore, illustrated is the structure of a photoelectric transformation device 1 according to one embodiment. Hereinafter, illustrated is a method of manufacturing the photoelectric transformation device 1 according to one embodiment.

Fabrication of Positive Electrode

A transparent conductor oxide (TCO) such as an indium tin oxide (ITO), tin oxide (SnO₂), tin oxide (FTO) doped with fluorine, antimony-containing indium tin oxide (ITO/ATO), zinc oxide ZnO₂, and the like may be coated on the surface of the aforementioned substrate 2 (a glass substrate, a transparent resin substrate, or the like) in a sputtering method, fabricating a transparent electrode 10.

The transparent electrode 10 may be formed as a counter electrode 4 by treating an active area on the surface (a region available for photoelectric transformation) with a metal such as platinum, gold, silver, copper, aluminum, rhodium, indium, and the like; a metal oxide such as indium tin oxide (ITO), tin oxide, tin oxide doped with fluorine, zinc oxide, and the like; a conductive carbon material; a conductive organic material, and like in a common method such as a sputtering method and like. In this way, a positive electrode may be fabricated.

Fabrication of Negative Electrode

A transparent electrode 10 may be formed on the surface of a substrate 2 according to the same method as the positive electrode to provide a negative electrode.

Next, a metal oxide particulate 31 (e.g., having a particle diameter of a nanometer size) such as TiO₂ and the like (see, for example, a more complete description above) and a binder resin for binding the metal oxide particulate 31 may be dispersed in water or an appropriate organic solvent, preparing a paste composition. The paste composition may be o coated in an active area (a region available for photoelectric transformation) on the surface of a transparent electrode 10. The paste composition may be applied, for example, by a screen-printing method, a coating method using a dispenser, a spin-coating method, a coating method using a squeezer, a dip coating method, a dispersion method, a die coating method, an inkjet printing method, and the like. The applied paste composition may be dried at a temperature (about 80° C. to about 200° C.), removing a solvent, and fired at a temperature (about 400° C. to about 600° C.), removing a binder resin, forming a metal oxide semiconductor layer.

A transparent electrode 10 and a substrate 2 including the metal oxide semiconductor layer may be dipped in a solution in which a sensitizing dye unit 33 is dissolved (e.g., an ethanol solution of a ruthenium complex-based dye or any of the dye materials and solvents described elsewhere) for a couple of hours to combine the sensitizing dye unit 33 with the surface of the metal oxide particulate 31, using an affinity of the connecting group of the sensitizing dye unit 33 for the surface of the metal oxide particulate 31. The metal oxide semiconductor layer combined with the sensitizing dye unit 33 may be dried at a temperature (about 40° C. to about 100° C.), removing a solvent, fabricating a photoelectrode 3. A method of combining the sensitizing dye unit 33 with the surface of the metal oxide particulate 31 is not limited to the aforementioned one.

A solvent for the solution in which a sensitizing dye is dissolved (hereinafter, refer to be as ‘dye solution’) may include, for example, an alcohol-based solvent such as ethanol, benzyl alcohol, and the like; a nitrile-based solvent such as acetonitrile, propinonitrile, and the like; a halogen-based solvent such as chloroform, dichloromethane, chlorobenzene, and the like; an ether-based solvent such as diethylether, tetrahydrofuran, and the like; an ester-based solvent such as acetic acid ethyl, acetic acid butyl, and the like; a ketone-based solvent such as acetone, methylethylketone, cyclohexanone, and the like; a carbonate ester-based solvent such as carbonate diethyl, carbonate propylene, and the like; a hydrocarbon-based solvent such as hexane, octane, benzene, toluene, and the like; or a solvent such as dimethyl formamide, dimethyl acetamide, dimethylsulfoxide, 1,3-dimethylimidazolinone, N-methylpyrrolidone, water, and the like but is not limited thereto. The dye solution may have a concentration ranging from about 0.01 mmol/L to about 10 mmol/L but is not limited thereto.

Joining of Positive Electrode and Negative Electrode

The positive electrode and negative electrode may be disposed to face each other, and a spacer 6 (e.g., an ionomer resin such as Himilan, DuPont-Mitsui Polychemicals Co., Ltd.) outside of each substrate 2. The resulting product may be thermally coalesced at about 120° C.

Preparation and Injection of an Electrolyte Solution into a Cell

The electrolyte solution 5 may be injected into an injection hole and then, spread throughout the cell, fabricating a photoelectric transformation device 1. The electrolyte solution 5 may include, for example, an acetonitrile electrolyte solution in which LiI and I₂ are dissolved. In addition, a mayenite-type compound is added to the electrolyte solution 5. A method of adding the mayenite type compound has no particular limit. The mayenite type compound may be uniformly dispersed.

In addition, the mayenite type compound has no particular limit. The mayenite type compound may include a C12A7 crystal type and the like including O²⁻ in the crystal lattice, a C12A7 electride type and the like in which an electron is substituted for O²⁻, a type in which halide ion, polyhalide ion, or a combination thereof is substituted for O²⁻, and the like. A method of synthesizing the mayenite-type compound is illustrated in detail in the following Examples.

A photoelectric transformation device 1 may be assembled by connecting a plurality of photoelectric transformation devices 1 and the like. For example, a plurality of photoelectric transformation devices 1 is connected in series to increase overall voltage generation.

Hereinbefore, one embodiment is illustrated in detail referring to the accompanied drawings, but the embodiments are not limited thereto. Each exemplary variation or modification is understood to belong to the technological scope described within the range of the patent claims by those who have common knowledge in a related art.

For example, a metal oxide particulate 31 may be described as an inorganic semiconductor particulate having a photoelectric transformation function and connected with a sensitizing dye on the surface and thus, sensitized. However, the inorganic semiconductor particulate according to one embodiment is not limited to the metal oxide particulate 31. For example, an inorganic semiconductor particulate may include silicon, germanium, Group III-V-based semiconductor, metal chalcogenide, and the like.

### Examples

The following examples illustrate this disclosure in more detail. These examples, however, are not in any sense to be interpreted as limiting the scope of this disclosure.

A dye sensitized solar cell fabricated using an electrolyte composition including a mayenite-type compound according to one embodiment was evaluated regarding photoelectric transformation efficiency and life-span characteristic.

Example of Manufacturing Dye-Sensitized Solar Cell

An example of manufacturing a dye-sensitized solar cell is illustrated.

Transparent Electrode

An FTO glass substrate (Type U-TCO, Asahi Techno Glass Corp.) was used as a transparent electrode including a fluorine-doped tin oxide layer (a transparent electrode layer).

Counter Electrode

A counter electrode was prepared by laminating a 150 nm-thick platinum layer (a platinum electrode layer) on an electric conductive layer of a FTO glass substrate (Type U-TCO, Asahi Techno Glass Corp.) including a fluorine-doped tin oxide layer in a sputtering method.

Preparation of Paste Composition for Photoelectrode and Titanium Oxide Photoelectrode

A titanium oxide photoelectrode was prepared. 2 ml of titanium tetra-n-propoxide, 4 ml of acetic acid, 1 ml of ion exchanger, 0.8 g of polyvinyl pyrroline, and 40 ml of 2-propanol were mixed to prepare a mixed solution. The mixed solution was spin-coated on a FTO glass substrate, dried at a room temperature, and fired at 450° C. in the air for one hour. The fired electrode was spin-coated with the same mixed solution and fired at 450° C. in the air for one hour.

Next, 3 g of titanium oxide (Nippon Aerosil Co., Ltd) P-25), 0.2 g of acetyl acetone, and 0.3 g of a surfactant (polyoxyethylene octylphenylether, Wako Pure Chemical Industries, Ltd.) were treated with 5.5 g of water and 1.0 g of ethanol using a bead mill. The resulting mixture was dispersed for 12 hours. Then, 1.2 g of polyethyleneglycol (#20,000) was added to the dispersion solution, preparing a paste composition. The paste composition was screen-printed to be 15 μm thick on the current-collecting electrode, dried at 150° C., and fired at 500° C. in the air for one hour, preparing a titanium oxide photoelectrode. The cell had an active area of about 0.25 cm².

Absorption of Sensitizing Dye

A sensitizing dye was adsorbed in the aforementioned titanium oxide electrode in the following method. A sensitizing dye for a photoelectric transformation (N719, Solaronix Co.) was dissolved in ethanol with a concentration of 0.6 mmol/L, preparing a dye solution. The titanium oxide electrode was dipped in the dye solution and then, allowed to stand at a room temperature for 24 hours. The dyed titanium oxide electrode was cleaned with ethanol on the surface and then, dipped in an alcohol solution of 2 mol % 4-t-butyl pyridine for 30 minutes and dried at a room temperature, preparing a photoelectrode preparing a dyed titanium oxide porous layer.

Preparation of Electrolyte Solution

An electrolyte solution was prepared as a standard electrolyte solution in the following method.

A solvent for dissolving an electrolyte may include 3-methoxy propinonitrile (3 MPN) as a volatile solvent, iodide (HMII) of N-methyl-N′-hexylimidazolium as an ionic liquid, or a solution prepared by dissolving 15 wt % of a polyvinylidenefluoride-hexafluoropropylene copolymer (PVDF-HFP) in 3-methoxy propinonitrile (3 MPN) as a gel electrolyte solution.

LiI: 0.1 M

I₂: 0.05 M

4-t-butyl pyridine: 0.5 M

propyl-2,3-dimethylimidazolium iodide: 0.6 M

Synthesis and Addition of Mayenite-Type Compounds

Mayenite type compound fto add to a standard electrolyte solution were synthesized in the following methods.

1) Synthesis of a Mayenite Type Compound

A calcium carbonate was combined with an aluminum oxide in order to obtain a mole ratio 12:7 in the resulting oxide. The resulting product was maintained at 1300° C. under the air atmosphere for 6 hours and then, cooled down. The sintered product was ground and sieved, preparing a powder with an average a particle diameter ranging from about 0.5 μm to 50 μm. The powder was a white insulator and identified from an X-ray diffraction analysis to be a C12A7 compound with a mayenite structure (hereinafter, referred to as ‘experimental material MA’).

2) Synthesis of a Conductive Mayenite-Type Compound

About 0.4 parts by weight of carbon powder with an average particle diameter of 10 μm were mixed with 100 parts by weight of the mayenite-type compound prepared in the aforementioned 1). The powder mixture was pressed with 200 kgf/cm² of a pressure, preparing a molded body with a diameter of 3 cm and a height of 3 cm (an experimental material A). The experimental material A included 1.9% of carbon atoms based on the total atoms of Ca and Al. The experimental material A was put in a carbon container with a cover and then, heated up to 1300° C. in a nitrogen flowing furnace under nitrogen gas atmosphere with an oxygen concentration of 0.6 volume % and maintained there for 2 hours.

A molded body (an experimental material B) after the heat treatment was dark green and identified to be a mayenite type compound from the X-ray diffraction analysis. The experimental material B had an electron density of 1.5×1020/cm³ and an electric conductivity of 1 S/cm or more. Accordingly, the prepared material was identified to be a conductive mayenite type compound (hereinafter, referred to as ‘experimental material MB’).

3) Synthesis of Iodine Adsorption Mayenite Type Compound

About 0.5 g of the synthesized mayenite type compound (experimental material MA) was charged in a quartz pipe. The quartz pipe was heated to heat the experimental material MA at 700° C. and then, filled with 0.002 mol/l of an iodine aqueous solution and nitrogen gas. Compared with X-ray diffraction patterns of the experimental material MA before and after the reaction, the diffraction pattern after the reaction was shifted toward a lower angle than the diffraction pattern before the reaction, which shows that the crystal after the reaction had a bigger unit lattice. Accordingly, the experimental material after the reaction (hereinafter, referred to as ‘experimental material MC’) was identified to have a crystal structure accepting iodine.

The prepared experimental materials MA, MB, and MC were respectively added to standard electrolyte solutions in an amount ranging from 0.1 wt % to 50 wt % and sufficiently dispersed therein, preparing each electrolyte solution respectively including the experimental material MA, MB, and MC.

Assembly of Photoelectric Transformation Cell

The fabricated photoelectrode and a counter electrode were assembled to fabricate a photoelectric transformation cell (a dye-sensitized solar cell) as a test sample as shown in FIG. 1. In other words, the photoelectrode and the counter electrode were fixed together with a spacer made of a resin film (a 50 μm-thick Himilan film, DuPont-Mitsui Polychemicals Co., Ltd.) therebetween and then, hot-pressed and sealed. Next, the electrolyte solution was injected into a predesigned hole to form an electrolyte solution layer. The electrolyte solution injection hole was hot-pressed and sealed in the aforementioned method. Then, a wire for measuring efficiency was respectively connected to a glass substrate.

Measurement Method of Transformation Efficiency

Each photoelectric transformation cell according to Examples and Comparative Examples was evaluated regarding transformation efficiency in the following method. A sample test cell was measured regarding I-V curve characteristics using a Keithley source meter (Model 2400), while the test cell was radiated with a light amount of 100 mW/cm² using an actinometer by assembling a solar simulator (#8116, Oriel Inc.) with an air mass filter as a light source. The transformation efficiency η (%) of the test cell was calculated using an open circuit voltage (Voc), short circuit current (Isc), and fill factor (ff) acquired from the I-V characteristic measurement according to the following equation 1. The transformation efficiency is provided in Table 1.

$$\begin{matrix}[ Equation 1 ] & \\ η ( \% ) = \frac{Voc ( V ) \times Isc ( mA ) \times ff}{100 ( mW \text{/} {cm}^{2} ) \times 0.25 {cm}^{2}} \times 100 & ( 1 )\end{matrix}$$

Accelerated Evaluation Method of Life-Span Characteristic

Each photoelectric transformation cell according to the Example and Comparative Examples were allowed to stand in a constant temperature and humidity chamber of 85° C. and humidity of 85% for 200 hours and measured regarding transformation efficiency in the aforementioned method. Then, a ratio was calculated of the maintained initial characteristic in transformation efficiency after being allowed to stand in the constant temperature & humidity chamber against the initial transformation efficiency (=(transformation efficiency after being allowed to stand in a constant temperature & humidity chamber)/(initial transformation efficiency)×100). The initial characteristic maintenance ratio is provided in Table 1.

TABLE 1

| | | | | | Initial characteristic |
|---|---|---|---|---|---|
| | | | Amount | Transformation | maintenance ratio at an |
| | Solvent | Mayenite | (%) | efficiency (%) | accelerated life-span test (%) |
| Example 1 | 3MPN | MA | 5 | 8.2 | 85 |
| Example 2 | HMII | MA | 5 | 7.5 | 95 |
| Example 3 | Gel electrolyte | MA | 5 | 7.8 | 90 |
| Example 4 | HMII | MB | 5 | 8.2 | 95 |
| Example 5 | HMII | MC | 5 | 8.0 | 95 |
| Example 6 | Gel electrolyte | MC | 0.1 | 7.5 | 90 |
| Example 7 | Gel electrolyte | MC | 1 | 8.0 | 90 |
| Example 8 | Gel electrolyte | MC | 5 | 8.3 | 90 |
| Example 9 | gel electrolyte | MC | 50 | 6.5 | 90 |
| Comparative | Acetonitrile | MA | 5 | 8.5 | 5 (electrolyte solution |
| Example 1 | | | | | volatilized) |
| Comparative | Acetonitrile | None | 0 | 8.0 | 5 (electrolyte solution |
| Example 2 | | | | | volatilized) |
| Comparative | 3MPN | None | 0 | 6.8 | 85 |
| Example 3 | | | | | |
| Comparative | HMII | None | 0 | 3.3 | 95 |
| Example 4 | | | | | |
| Comparative | Gel electrolyte | None | 0 | 5.5 | 90 |
| Example 5 | | | | | |

As shown in Table 1, the photoelectric transformation cells including an electrolyte solution including a mayenite type compound according to Examples 1 to 9 all had excellent photoelectric transformation efficiency and life-span characteristic.

On the other hand, the photoelectric transformation cells including volatile acetonitrile as a solvent according to Comparative Examples 1 and 2 had excellent photoelectric transformation efficiency but deteriorated life-span characteristic due to volatilization of an electrolyte solution.

In addition, as for a photoelectric transformation cell including 3 MPN as a solvent with a high boiling point according to Example 1 and Comparative Example 3, the one including a mayenite type compound according to Example 1 had improved transformation efficiency compared with the one including no mayenite type compound according to Comparative Example 3.

In addition, as for a photoelectric transformation cell including HMII or a gel electrolyte as a solvent, the one including a mayenite type compound according to Examples 2 and 3 had improved transformation efficiency compared with the one including no mayenite type compound according to Comparative Examples 4 and 5. When a mayenite type compound was added to an electrolyte solution, a photoelectric transformation cell including the mayenite compound was found to have the same excellent life-span characteristic but sharply improved transformation efficiency.

In this way, an electrolyte solution including a mayenite type compound may improve photoelectric transformation efficiency of a photoelectric transformation device such as a dye-sensitized solar cell and the like and particularly, prevent volatilization of an electrolyte solution and thus, maintain excellent life-span characteristic and improve photoelectric transformation efficiency due to the mayenite type compound. An electrolyte composition may be provided for a photoelectric transformation device that does not reduce ion conductivity and long life reliability of a photoelectric transformation device by suppressing leakage or volatilization of an electrolyte solution out of a photoelectric transformation device and elution of an electrode active material.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An electrolyte composition for a photoelectric transformation device, comprising:
a redox material; and
a mayenite type compound.

2. The electrolyte composition as claimed in claim 1, wherein the redox material is a halide ion, a polyhalide ion, or a combination thereof.

3. The electrolyte composition as claimed in claim 1, wherein the mayenite type compound is 12CaO.7Al₂O₃ or 12SrO.7Al₂O₃.

4. The electrolyte composition as claimed in claim 1, wherein the mayenite type compound is present in the electrolyte composition in an amount of about 0.1 wt % to 50 wt % based on an entire amount of the electrolyte composition.

5. The electrolyte composition as claimed in claim 1, wherein the mayenite type compound includes halide ions, polyhalide ions, or a combination thereof inside at least some pores of a crystal lattice of the mayenite type compound such that the halide ions, polyhalide ions, or a combination thereof inside at least some pores of the crystal lattice of the mayenite type compound are unable to combine with a cation.

6. The electrolyte composition as claimed in claim 1, further including a gel electrolyte, ionic liquid, or a combination thereof.

7. The electrolyte composition as claimed in claim 6, wherein the ionic liquid is propyl-2,3-dimethylimidazolium iodide or N-methyl-N′-hexylimidazolium iodide.

8. The electrolyte composition as claimed in claim 6, wherein the gel electrolyte includes polyacrylonitrile, polyvinylidene fluoride or a polyvinylidene fluoride-hexafluoropropylene copolymer.

9. A photoelectric transformation device comprising:
an electrolyte layer including an electrolyte composition including a redox material and a mayenite type compound.

10. The photoelectric transformation device as claimed in claim 9, wherein the redox material is a halide ion, a polyhalide ion, or a combination thereof.

11. The photoelectric transformation device as claimed in claim 9, wherein the mayenite type compound is present in the electrolyte composition in an amount of about 0.1 wt % to 50 wt % based on an entire amount of the electrolyte composition.

12. The photoelectric transformation device as claimed in claim 9, wherein the mayenite type compound includes halide ions, polyhalide ions, or a combination thereof inside at least some pores of a crystal lattice of the mayenite type compound such that the halide ions, polyhalide ions, or a combination thereof inside at least some pores of the crystal lattice of the mayenite type compound are unable to combine with a cation.

13. The photoelectric transformation device as claimed in claim 9, wherein the electrolyte composition further includes a gel electrolyte, ionic liquid, or a combination thereof

14. The photoelectric transformation device as claimed in claim 9, which is a dye sensitized solar cell.

15. A solar cell comprising:
an electrolyte layer between a photoelectrode and a counter electrode, the electrolyte including an electrolyte composition that includes a mayenite type compound.

16. The dye sensitized solar cell as claimed in claim 15, wherein the electrolyte further includes a redox material that is a halide ion, a polyhalide ion, or a combination thereof.
